(19) United States
(12) Patent Application Publication
(10) Pub. No.: US 2024/0290638 A1
(43) Pub. Date: Aug. 29, 2024

(54) DEPOSITION OR ETCH CHAMBER WITH COMPLETE SYMMETRY AND HIGH TEMPERATURE SURFACES

(71) Applicant: Applied Materials, Inc., Santa Clara, CA (US)

(72) Inventors: Dmitry Lubomirsky, Cupertino, CA (US); Kaushik Alayavalli, Sunnyvale, CA (US); Amit Ashok Hattangadi, Bengaluru (IN); Bhawesh Agrawal, Bangalore (IN); Vishwas Basavarajaiah Somashekar, Bangalore (IN); Chethan Somanahalli Malleshappa, Bengaluru (IN)

(73) Assignee: Applied Materials, Inc., Santa Clara, CA (US)

(21) Appl. No.: 18/174,534

(22) Filed: Feb. 24, 2023

(51) Int. Cl. H01L 21/67; H01L 21/687

(52) U.S. Cl. CPC H01L 21/6719; H01L 21/67173; H01L 21/68742

(57) ABSTRACT

Exemplary semiconductor processing systems may include a chamber having a body having a sidewall and a base. The chamber may include a pumping liner atop the body and a faceplate atop the pumping liner. The chamber may include a substrate support. The substrate support may include a plate and a shaft. The chamber may include a seal plate coupled with the shaft below the plate. The seal plate may have a greater diameter than the plate. The seal plate may include an RF gasket outward of the plate. The substrate support and the seal plate may be translatable between a transfer position in which the RF gasket is vertically spaced apart from the pumping liner and a process position in which the RF gasket is in contact with the pumping liner. A processing region may be isolated from an environment below the sealing plate when in the process position.

### TECHNICAL FIELD

The present technology relates to components and apparatuses for semiconductor manufacturing. More specifically, the present technology relates to processing chamber components and other semiconductor processing equipment.

### BACKGROUND OF THE INVENTION

Integrated circuits are made possible by processes which produce intricately patterned material layers on substrate surfaces. Producing patterned material on a substrate requires controlled methods for forming and removing material. Precursors are often delivered to a processing region and distributed to uniformly deposit or etch material on the substrate. Many aspects of a processing chamber may impact process uniformity, such as uniformity of process conditions within a chamber, uniformity of flow through components, as well as other process and component parameters. Even minor discrepancies across a substrate may impact the formation or removal process.

Thus, there is a need for improved systems and methods that can be used to produce high quality devices and structures. These and other needs are addressed by the present technology.

### BRIEF SUMMARY OF THE INVENTION

Exemplary semiconductor processing systems may include a processing chamber. The chamber may include a chamber body having a sidewall and a base. The chamber may include a pumping liner seated atop the chamber body. The chamber may include a faceplate seated atop the pumping liner. The chamber may include a substrate support disposed within the chamber body. The substrate support may include a support plate and a shaft coupled with the support plate. The chamber may include a seal plate that is coupled with the shaft and that extends below the support plate. The seal plate may have a greater diameter than the support plate. The seal plate may include an RF gasket disposed radially outward of the support plate. The substrate support and the seal plate may be vertically translatable within the chamber body between a transfer position in which the RF gasket is vertically spaced apart from a bottom surface of the pumping liner and a process position in which the RF gasket is in contact with the bottom surface of the pumping liner. A processing region formed between the faceplate and the support plate may be isolated from an environment below the sealing plate when the substrate support and the seal plate are in the process position.

In some embodiments, the systems may include a dielectric spacer disposed between the pumping liner and the faceplate. The pumping liner may be symmetrical about a central axis.

The processing region may be symmetrical with respect to each of gas flow, thermal distribution, and RF distribution. The processing region may be structurally symmetrical. The systems may include a bellow that extends along at least a portion of a length of the shaft and that seals isolates an interior of the bellow from a higher pressure environment. The bellow may extend between a bottom surface of the base of the chamber body and a support on which the shaft of the substrate support is mounted. The systems may include a plurality of lift pins that are extendible through the support plate. Each of the plurality of lift pins may include a spring-loaded plunger that is coupled with the base of the chamber body. Each of the plurality of lift pins may include a pin member that is biased by the spring-loaded plunger in an upward direction. Each of the plurality of lift pins may include a pin guide that is coupled with one or both of the seal plate and a head of the pin member. Each of the plurality of lift pins may include a pin bellow that extends between the seal plate and the base of the chamber body. The spring-loaded plunger and the pin member may separate as the substrate support is raised to the process position such that the pin member hangs from the substrate support when in the process position.

The spring-loaded plunger may include a base that is coupled with the base and that defines a central recess. The spring-loaded plunger may include a plunger body that is slidingly received within the central recess. The spring-loaded plunger may include a spring that is coupled between a base of the central recess and a bottom end of the plunger body. The systems may include a transfer chamber coupled with the processing chamber. The systems may include at least one additional processing chamber that shares the base of the chamber body with the chamber and the transfer chamber. The processing region of the processing chamber and a processing region of the at least one additional processing chamber may be isolated from one another when the substrate support is in the process position.

Some embodiments of the present technology may encompass semiconductor processing systems that include a transfer chamber that comprises at least one transfer apparatus. The systems may include a plurality of processing chambers that are horizontally aligned with one another. Each of the plurality of processing chambers may be coupled with the transfer chamber. Each of the plurality of processing chambers may include a chamber body having a sidewall and a base. An interior of the chamber body may be accessible to the at least one transfer apparatus. Each chamber may include a pumping liner seated atop the chamber body. Each chamber may include a faceplate seated atop the pumping liner. Each chamber may include a substrate support disposed within the chamber body. The substrate support may include a support plate and a shaft coupled with the support plate. Each chamber may include a seal plate that is coupled with the shaft and that extends below the support plate. The seal plate may have a greater diameter than the support plate. The seal plate may include an RF gasket disposed radially outward of the support plate. The substrate support and the seal plate may be vertically translatable within the chamber body between a transfer position in which the RF gasket is vertically spaced apart from a bottom surface of the pumping liner and a process position in which the RF gasket is in contact with the bottom surface of the pumping liner. A processing region formed between the faceplate and the support plate may be isolated from an environment below the sealing plate when the substrate support and the seal plate are in the process position.

In some embodiments, the base of each of the plurality of processing chambers may form a bottom surface of the transfer chamber. The plurality of processing chambers may be arranged in a single row on one side of the at least one transfer apparatus. The plurality of processing chambers may be arranged in a plurality of rows on multiple sides of the at least one transfer apparatus. The systems may include a lid plate that is seated atop the chamber body of each of the plurality of processing chambers.

Some embodiments of the present technology may encompass lift pin assemblies. The assemblies may include a spring-loaded plunger. The assemblies may include a pin guide that is disposed above the spring-loaded plunger. The assemblies may include a pin member that is disposed within the pin guide and that is biased by the spring-loaded plunger in an upward direction. The assemblies may include a pin bellow positioned about the pin guide and coupled with a head of the pin member. In some embodiments, the pin member may include split pins.

Such technology may provide numerous benefits over conventional systems and techniques. For example, embodiments of the present technology may provide chambers that include symmetrical processing regions. Such symmetrical processing regions may improve temperature, flow, and RF uniformity within the processing region, and thus may improve film uniformity across substrates being processed. Additionally, embodiments may provide chambers in which the processing chamber is completely or substantially isolated from the transfer region and cooler components, which may help improve the utilization rate of gas, as less bottom purge gas is needed, which may reduce the dilution of process gases by such purge gases. Additionally, as the cooler components are not exposed to the process environment, less chamber clean time is needed. Embodiments may also provide non-motorized lift pins while eliminating the need for vertical motion of transfer robots. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to some embodiments of the present technology.

FIG. 2 shows a schematic cross-sectional view of an exemplary plasma system according to some embodiments of the present technology.

FIG. 3 shows a schematic cross-sectional view of an exemplary processing chamber according to some embodiments of the present technology.

FIG. 4A shows a schematic cross-sectional view of an exemplary processing chamber in a transfer position according to some embodiments of the present technology.

FIG. 4B shows a schematic cross-sectional view of the processing chamber of FIG. 4A in a process position according to some embodiments of the present technology.

FIGS. 5A and 5B show isometric views of exemplary processing systems according to some embodiments of the present technology.

FIGS. 6A-6D show schematic cross-sectional views of lift pin actuation of an exemplary processing system according to some embodiments of the present technology.

FIGS. 7A-7C show schematic cross-sectional views of a lift pin assembly according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION OF THE INVENTION

Plasma enhanced deposition processes may energize one or more constituent precursors to facilitate film formation on a substrate. Any number of material films may be produced to develop semiconductor structures, including conductive and dielectric films, as well as films to facilitate transfer and removal of materials. For example, hardmask films may be formed to facilitate patterning of a substrate, while protecting the underlying materials to be otherwise maintained. In many processing chambers, a number of precursors may be mixed in a gas panel and delivered to a processing region of a chamber where a substrate may be disposed. While components of the lid stack may impact flow distribution into the processing chamber, many other process variables may similarly impact uniformity of deposition.

As device features reduce in size, tolerances across a substrate surface may be reduced, and material property differences across a film may affect device realization and uniformity. Many chambers include a characteristic process signature, which may produce residual non-uniformity across a substrate. Temperature differences, flow pattern uniformity, and other aspects of processing may impact the films on the substrate, creating film uniformity differences across the substrate for materials produced or removed. For example, turbulent deposition gas flow and/or misalignment of apertures of a blocker plate and faceplate of a gas box may lead to non-uniform flow of deposition gases. In some instances, the blocker plate may not uniformly distribute flow of precursors to edge regions of a substrate. Additionally, in some embodiments a substrate support or heater on which a substrate is disposed may include one or more heating mechanisms to heat a substrate. When heat is delivered or lost differently between regions of a substrate, the film deposition may be impacted where, for example, warmer portions of the substrate may be characterized by thicker deposition or different film properties relative to cooler portions. This temperature non-uniformity may be attributable, for example, to temperature fluctuations about the shaft of the pedestal and may particularly affect edge regions of substrates.

The present technology overcomes these challenges by using processing chamber designs that provide symmetry within the processing environment. For example, the chambers described herein may provide symmetric gas flow, thermal distribution, and RF distribution, which may improve deposition characteristics. Additionally, the chamber designs may include processing regions that are isolated from the transfer region and cooler components, which may reduce the need for use of purge gases during processing operations and may therefore reduce dilution of process gases, which may increase the material efficiency of the chamber. Additionally, the isolation of the processing region from the transfer region may enable a number of processing chambers within a single system to be operated independently of one another.

Embodiments may also utilize non-motorized lift pins, which may enable a simplified design that eliminates the need for vertical motion of a transfer robot to handoff substrates with the substrate support. Accordingly, the present technology may produce improved film deposition characterized by improved thickness and material property uniformity across a surface of the substrate.

Although the remaining disclosure will routinely identify specific deposition processes utilizing the disclosed technology, it will be readily understood that the systems and methods are equally applicable to other deposition and cleaning chambers, as well as processes as may occur in the described chambers. Accordingly, the technology should not be considered to be so limited as for use with these specific deposition processes or chambers alone. The disclosure will discuss one possible system and chamber that may include lid stack components according to embodiments of the present technology before additional variations and adjustments to this system according to embodiments of the present technology are described.

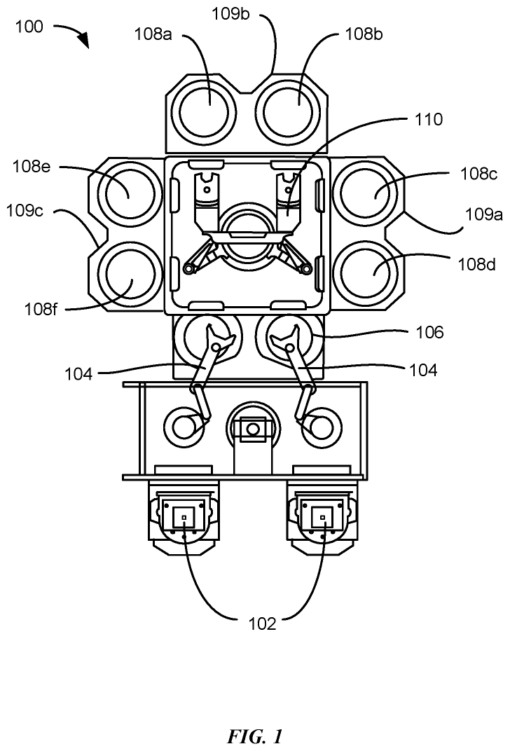

FIG. 1 shows a top plan view of one embodiment of a processing system 100 of deposition, etching, baking, and curing chambers according to embodiments. In the figure, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber 108a-f, can be outfitted to perform a number of substrate processing operations including formation of stacks of semiconductor materials described herein in addition to plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, annealing, curing and/or etching a dielectric or other film on the substrate. In one configuration, two pairs of the processing chambers, e.g., 108c-d and 108e-f, may be used to deposit dielectric material on the substrate, and the third pair of processing chambers, e.g., 108a-b, may be used to etch the deposited dielectric. In another configuration, all three pairs of chambers, e.g., 108a-f, may be configured to deposit stacks of alternating dielectric films on the substrate. Any one or more of the processes described may be carried out in chambers separated from the fabrication system shown in different embodiments. It will be appreciated that additional configurations of deposition, etching, annealing, and curing chambers for dielectric films are contemplated by system 100.

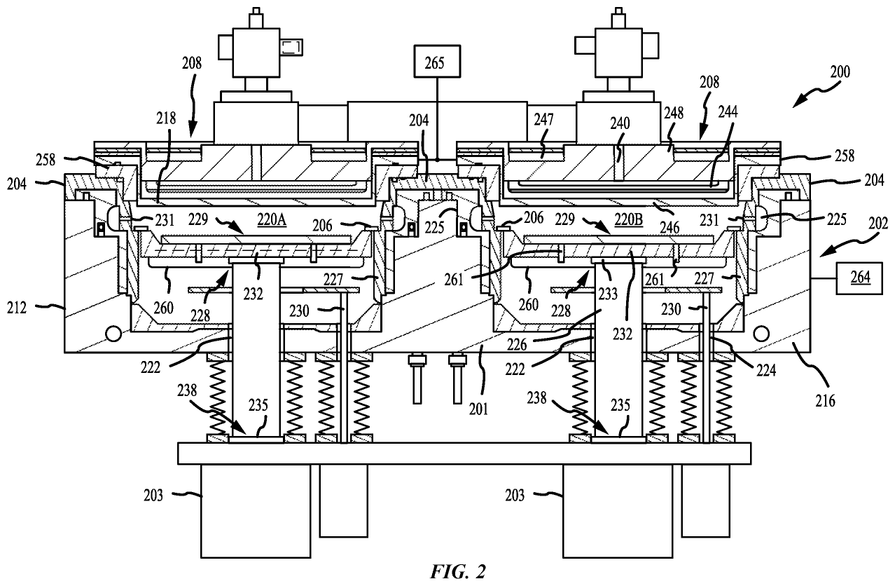

FIG. 2 shows a schematic cross-sectional view of an exemplary plasma system 200 according to some embodiments of the present technology. Plasma system 200 may illustrate a pair of processing chambers 108 that may be fitted in one or more of tandem sections 109 described above, and which may include faceplates or other components or assemblies according to embodiments of the present technology. The plasma system 200 generally may include a chamber body 202 having sidewalls 212, a bottom wall or base 216, and an interior sidewall 201 defining a pair of processing regions 220A and 220B. Each of the processing regions 220A-220B may be similarly configured, and may include identical components.

For example, processing region 220B, the components of which may also be included in processing region 220A, may include a pedestal 228 disposed in the processing region through a passage 222 formed in the base 216 in the plasma system 200. The pedestal 228 may provide a heater adapted to support a substrate 229 on an exposed surface of the pedestal, such as a body portion. The pedestal 228 may include heating elements 232, for example resistive heating elements, which may heat and control the substrate temperature at a desired process temperature. Pedestal 228 may also be heated by a remote heating element, such as a lamp assembly, or any other heating device.

The body of pedestal 228 may be coupled by a flange 233 to a stem 226. The stem 226 may electrically couple the pedestal 228 with a power outlet or power box 203. The power box 203 may include a drive system that controls the elevation and movement of the pedestal 228 within the processing region 220B. The stem 226 may also include electrical power interfaces to provide electrical power to the pedestal 228. The power box 203 may also include interfaces for electrical power and temperature indicators, such as a thermocouple interface. The stem 226 may include a base assembly 238 adapted to detachably couple with the power box 203. A circumferential ring 235 is shown above the power box 203. In some embodiments, the circumferential ring 235 may be a shoulder adapted as a mechanical stop or land configured to provide a mechanical interface between the base assembly 238 and the upper surface of the power box 203.

A rod 230 may be included through a passage 224 formed in the bottom wall 216 of the processing region 220B and may be utilized to position substrate lift pins 261 disposed through the body of pedestal 228. The substrate lift pins 261 may selectively space the substrate 229 from the pedestal to facilitate exchange of the substrate 229 with a robot utilized for transferring the substrate 229 into and out of the processing region 220B through a substrate transfer port 260.

A chamber lid 204 may be coupled with a top portion of the chamber body 202. The lid 204 may accommodate one or more precursor distribution systems 208 coupled thereto. The precursor distribution system 208 may include a precursor inlet passage 240 which may deliver reactant and cleaning precursors through a gas delivery assembly 218 into the processing region 220B. The gas delivery assembly 218 may include a gasbox 248 having a blocker plate 244 disposed intermediate to a faceplate 246. A radio frequency (“RF”) source 265 may be coupled with the gas delivery assembly 218, which may power the gas delivery assembly 218 to facilitate generating a plasma region between the faceplate 246 of the gas delivery assembly 218 and the pedestal 228, which may be the processing region of the chamber. In some embodiments, the RF source may be coupled with other portions of the chamber body 202, such as the pedestal 228, to facilitate plasma generation. A dielectric isolator 258 may be disposed between the lid 204 and the gas delivery assembly 218 to prevent conducting RF power to the lid 204. A shadow ring 206 may be disposed on the periphery of the pedestal 228 that engages the pedestal 228.

An optional cooling channel 247 may be formed in the gasbox 248 of the gas distribution system 208 to cool the gasbox 248 during operation. A heat transfer fluid, such as water, ethylene glycol, a gas, or the like, may be circulated through the cooling channel 247 such that the gasbox 248 may be maintained at a predefined temperature. A liner assembly 227 may be disposed within the processing region 220B in close proximity to the sidewalls 201, 212 of the chamber body 202 to prevent exposure of the sidewalls 201, 212 to the processing environment within the processing region 220B. The liner assembly 227 may include a circumferential pumping cavity 225, which may be coupled to a pumping system 264 configured to exhaust gases and byproducts from the processing region 220B and control the pressure within the processing region 220B. A plurality of exhaust ports 231 may be formed on the liner assembly 227. The exhaust ports 231 may be configured to allow the flow of gases from the processing region 220B to the circumferential pumping cavity 225 in a manner that promotes processing within the system 200.

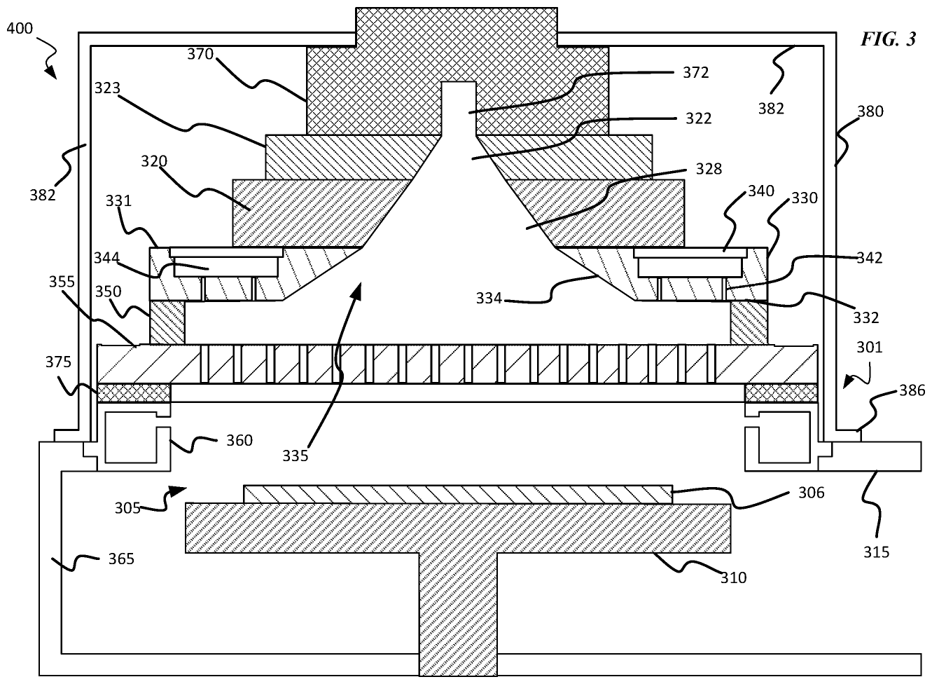

FIG. 3 shows a schematic partial cross-sectional view of an exemplary processing system 300 according to some embodiments of the present technology. FIG. 3 may illustrate further details relating to components in system 200. System 300 is understood to include any feature or aspect of system 200 discussed previously in some embodiments. The system 300 may be used to perform semiconductor processing operations including deposition of hardmask materials as previously described, as well as other deposition, removal, and cleaning operations. System 300 may show a partial view of the chamber components being discussed and that may be incorporated in a semiconductor processing system. Any aspect of system 300 may also be incorporated with other processing chambers or systems as will be readily understood by the skilled artisan.

As noted, FIG. 3 may illustrate a portion of a processing chamber 301. The chamber 301 may include a number of lid stack components, which may facilitate delivery or distribution of materials through the processing chamber 301 into a processing region 305, such as where a substrate 306 may be positioned on a pedestal 310, for example. A chamber lid plate 315 may extend across one or more plates of the lid stack and may provide structural support for components, such as a remote plasma source (“RPS”) unit 370, which may provide precursors or plasma effluents for chamber cleaning or other processing operations. In some embodiments the RPS unit 370 may include any structure or device that may generate a plasma remote from the processing region 305 and subsequently deliver the plasma to the processing region 305. The RPS unit 370 may be stabilized on the chamber lid plate 315, oftentimes with a number of components disposed between the RPS unit 370 and the lid plate 315. Some embodiments may utilize additional support members (not shown) that may couple with the processing chamber 301 at one or more positions about the processing chamber 301 to properly distribute the weight of the RPS unit 370 to protect components from sheer or other stresses related to the weight of the RPS unit 370. The RPS unit 370 may include at least one outlet 372 by which precursors or plasma effluents may be delivered to the chamber 301.

An output manifold 320 may be seated on and/or within the lid plate 315. The output manifold 320 may define a central aperture 328 that is fluidly coupled with an outlet of the RPS unit 370. In some embodiments, one or more spacers and/or isolators 323 may be positioned between the RPS unit 370 and the output manifold 320. The central aperture 328 and/or a gas lumen 322 defined through the isolator 323 may taper from a narrow top portion to a wide bottom portion in some embodiments.

Processing chamber 301 may also include a gasbox 330 that is positioned beneath the output manifold 320. Gasbox 330 may be characterized by a first surface 331 on an inlet side and a second surface 332 on an outlet side that may be opposite the first surface. Gasbox 330 may include an inner wall 334 that defines a central fluid lumen 335. All or a portion of the inner wall 334 may taper outward from the inlet side to the outlet side such that the central fluid lumen 335 provides an expansion volume for gases flowing from the RPS unit 370 and/or output manifold 320. The taper of the inner wall 334 may be constant along all of the length of the inner wall 334 such that the central fluid lumen 335 has a generally conical frustum shape. For example, a degree of taper of the inner wall 334 relative to vertical may be greater than or about 45°, greater than or about 50°, greater than or about 55°, greater than or about 60°, greater than or about 65°, greater than or about 70°, greater than or about 75°, greater than or about 80°, or more. The taper of the inner wall 334 may be constant along only a portion of the wall. For example, the inner wall 334 may include two or more sections having a different degrees of taper. As just one example, a top section of the inner wall 334 may have a steeper degree of taper relative to vertical, while a lower section of the inner wall 334 may have a lesser degree of taper. For example, the top section of the inner wall 334 may have a degree of taper relative to vertical of less than or about 70°, less than or about 65°, less than or about 60°, greater than or about 55°, or less. The lower section of the inner wall 334 may have a degree of taper relative to vertical of greater than or about 55°, greater than or about 60°, greater than or about 65°, greater than or about 70°, greater than or about 75°, greater than or about 80°, or more. The inner wall 334 may taper linearly outward and/or may taper outward in a curved manner. In some embodiments, a degree of taper of the inner wall 334 may match a degree of taper of the central aperture 328 and/or a gas lumen 322, while in other embodiments a degree of taper of the inner wall 334 may be less than or greater than a degree of taper of the central aperture 328 and/or a gas lumen 322.

Gasbox 330 may also define one or more channels that may be fluidly accessed through the gasbox 330, and may allow multiple precursors to be delivered through the lid stack in a variety of flow profiles. For example, gasbox 330 may define an annular channel 340 extending within the gasbox 330, and which may be recessed from first surface 331. As will be explained further below, annular channel 340 may be fluidly accessed through an inlet aperture, which may be positioned at any location about the gasbox 330, and may afford coupling for one or more precursors to be delivered from a gas panel or manifold. The inlet aperture may extend through first surface 331, for providing precursors into the gasbox 330. In some embodiments, annular channel 340 may be concentric with the central fluid lumen 335 of the gasbox 330. Gasbox 330 may also define one or more outlet apertures 342. Outlet apertures 342 may be defined through the annular channel 340, and may extend from annular channel 340 through second surface 332 of the gasbox 330. Hence, one or more precursors delivered into annular channel 340 through the gasbox 330 may bypass the RPS unit 370 and be delivered to one or more outer regions of the gasbox 330.

Gasbox 330 may include additional features. For example, gasbox 330 may define a cooling channel 344, which may allow a cooling fluid to be flowed about the gasbox 330, and which may allow additional temperature control. As illustrated, the cooling channel 344 may be defined in the first surface 331 of the gasbox 330, and a lid may extend about the cooling channel to form a hermetic seal. Cooling channel 344 may extend about central fluid lumen 335, and may also be concentric with the central fluid lumen 335. As illustrated, annular channel 340 may be formed or defined within the gasbox 330 between the cooling channel 344 and the second surface of the gasbox 330. In some embodiments the annular channel 340 may be vertically aligned with the cooling channel 344, and may be offset from the cooling channel 344 within a depth of the gasbox 330. To form the annular channel 340, in some embodiments the gasbox 330 may include one or more stacked plates. The plates may be bonded, welded, or otherwise coupled together to form a complete structure.

For example, gasbox 330 may include at least one plate, and may include two, three, four, or more plates depending on the features formed. As illustrated, gasbox 330 may include two or three plates, which may allow multiple paths to be formed to further distribute precursors towards the annular channel 340. For example, with a single point of delivery, uniformity may be achieved by modulating conductance within the channel relative to the outlet apertures. However, by utilizing one or more conductance paths defined within the gasbox 330, precursors may be delivered to multiple locations within the annular channel 340, which may increase uniformity of delivery through the gasbox 330, and may allow larger diameter outlet apertures without sacrificing delivery uniformity.

Semiconductor processing chamber 301 may also include additional components in some embodiments, such as an annular spacer 350 and a faceplate 355. Faceplate 355 may define a number of apertures that extend through a thickness of the faceplate 355 that enable precursors and/or plasma effluents to be delivered to the processing region 305, which may be at least partially defined from above by the faceplate 355. An inner diameter of the annular spacer 350 may be positioned radially outward of the apertures of the faceplate 355 so as to not obstruct the flow of gas through the faceplate 355. The annular spacer 350 may define a volume 352 that is fluidly coupled with the central fluid lumen 335. The volume 352 may be a first location through the lid stack where precursors delivered to the central fluid lumen 335 of the gasbox 330 and precursors delivered to the annular channel 340 of the gasbox 330 may intermix. Volume 352 may be fluidly accessible from both central fluid lumen 335 and the outlet apertures 342. Precursors delivered into the volume 352 may then at least partially mix or overlap before continuing through the lid stack. By allowing an amount of mixing prior to contacting the substrate surface, an amount of overlap may be provided, which may produce a smoother transition at the substrate, and may limit an interface from forming on a film or substrate surface.

An inner wall of the annular spacer 350 may be positioned radially outward from a bottom end of the central fluid lumen 335. This may result in a stepped transition between a bottom end of the central fluid lumen 335 and the volume 352 that allows gas flow to expand to a full exposed area of the faceplate 355 upon passing into the volume 352. For example, the volume 352 may have a generally rectangular cross-section such that gas introduced to the central fluid lumen 335 is initially constrained by a frustum-shaped inner wall 334 before expanding to volume 352 that in constrained by an inner wall of the annular spacer 350 that has a larger diameter than a bottom of the inner wall 334 of the gasbox 330.

By providing a tapered expansion volume within and/or below the gasbox 330, better

RPS-only cleaning uniformity and wider reach may be achieved. In particular, providing an expansion volume further from the faceplate 355 provides more space and distance for precursors and plasma effluents to expand radially outward to more effectively distribute cleaning gases to the outer periphery of the faceplate 355 and other chamber components, such as the edge of the pedestal 310 and/or a pumping liner 360. The increased distribution of the cleaning gases to the outer periphery of the faceplate may also help prevent arcing from occurring during certain deposition procedures, such as those that utilize conductive elements such as carbon. Additionally, such a gasbox design may help more evenly distribute deposition gases through the faceplate 355 to generate a more uniform film on wafer.

The faceplate 355 may be seated atop the pumping liner 360, which may be seated atop a body 365 of the chamber 301 and/or lid plate 315. The pumping liner 360 may be coupled with an exhaust system of the chamber 301, such as via one or more forelines. The pumping liner 360 may define a number of apertures through an inner wall of the pumping liner 360 that may enable gases to be pumped out of the chamber 301. In some embodiments, a dielectric spacer 375 may be seated between the pumping liner 360 and the faceplate 355. The dielectric spacer 375 may thermally and/or electrically isolate the faceplate 355 from the pumping liner 360. For example, in some embodiments, the pumping liner 360 may be formed from a conductive material, such as aluminum, and may form a part of an RF return path as will be discussed in greater detail below.

In some embodiments, the lid stack components (e.g., some or all components from the isolator 323 to the pumping liner 360) which are seated atop the chamber body 365 and/or lid plate 315 may be housed beneath an annular cover 380. Annular cover 380 may define a central aperture that may receive and seal against a portion of the RPS unit 370, such as an outlet end of the RPS unit 370. The annular cover 380 may include a top plate 382 that extends outward beyond a periphery of the lid stack components. A sidewall 384, such as a cylindrical sidewall, may extend downward from a peripheral edge of the top plate 382 and may terminate in a flange 386. Flange 386 may extend radially outward from the sidewall 384 and may be coupled with the lid plate 315 to cover the lid stack components.

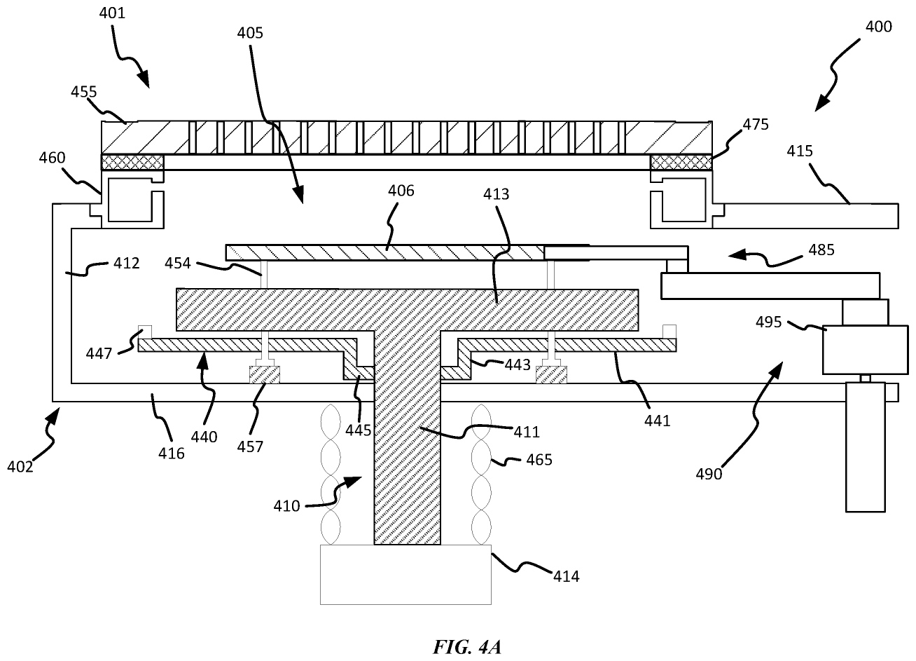

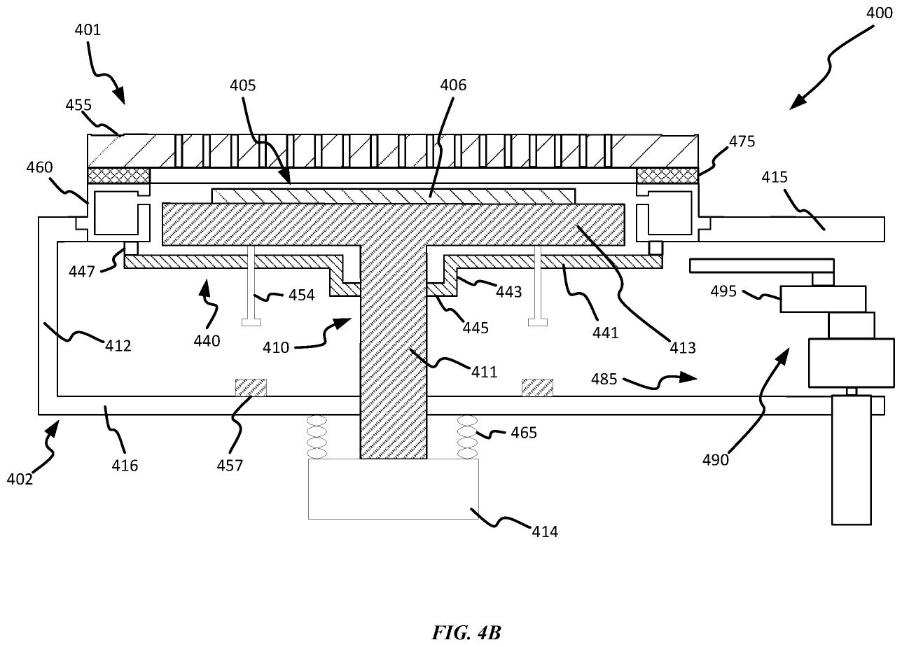

FIGS. 4A and 4B show a schematic partial cross-sectional view of an exemplary processing system 400 according to some embodiments of the present technology. FIGS. 4A and 4B may illustrate further details relating to components in system 200 or system 300. System 400 is understood to include any feature or aspect of system 200 discussed previously in some embodiments. The system 400 may be used to perform semiconductor processing operations including deposition of hardmask materials as previously described, as well as other deposition, removal, and cleaning operations. System 400 may show a partial view of the chamber components being discussed and that may be incorporated in a semiconductor processing system. Any aspect of system 400 may also be incorporated with other processing chambers or systems as will be readily understood by the skilled artisan.

FIGS. 4A and 4B may illustrate a portion of a processing chamber 401, although as will be discussed below any number of processing chambers may be included in system 400, with some or all of the processing chambers having a similar structure as processing chamber 401. Processing chamber 401 may include any of the features described in relation to chambers 108 and/or 301. For example, each chamber 401 may include a chamber body 402 that may include one or more sidewalls 412 and a base 416. In some embodiments, multiple processing chambers 401 may share one or more of the sidewalls 412 and/or the base 416. Similarly, a transfer chamber 495 may be coupled with each processing chamber 401 and may share one or more of the sidewalls 412 and/or the base 416 with at least one of the processing chambers 401. At least one sidewall 412 may define or include an opening 485 and/or slit valve that couples an interior of the processing chamber 401 with the transfer chamber 495. A chamber lid plate 415 may be seated atop the chamber body, such as atop one or more of the sidewalls 412. The lid plate 415 may extend across some or all of the processing chambers 401 within system 400, and in some embodiments may also extend over the transfer chamber 495. The lid plate 415 may define a number of apertures that may each be aligned with a respective one of the processing chambers 401, which may provide access for lid stack components (such as gas distribution components) to be seated to deliver one or more gases to a processing region 405 of the processing chamber 401.

As discussed above in relation to systems 200 and 300, a number of lid stack components may be seated atop the lid plate 415. For example, a pumping liner 460 may be seated atop the chamber body and lid plate 415, which an interior of the pumping liner 460 defining at least a portion of a lateral boundary of the processing region 405. In some embodiments, a dielectric spacer 475 may be seated atop the pumping liner 460, with the dielectric spacer 475 being disposed between and isolating the pumping liner 460 from a faceplate 455 seated atop the pumping liner 460. This may thermally and/or electrically isolate the pumping liner 460 from the faceplate 455. The faceplate 455 may define a top boundary of the processing region 405.

Each processing chamber 401 may include a substrate support 410 that may include a shaft 411 that extends through the base 416. The shaft 411 may be mounting on and/or otherwise coupled with a support 414 (which may be or include a linear actuator or other lift mechanism that controls the translation of the substrate support 410) that is disposed below the base 416. The substrate support 410 may also include a support plate 413 that is coupled with the shaft 411 and which defines a substrate-receiving surface. The substrate support 410 may be translatable within the processing chamber 401 between a lower transfer position (such as shown in FIG. 4A) in which the transfer apparatus 495 may deliver substrates to and from the support plate 413 and a raised process position (such as shown in FIG. 4B) in which a substrate 406 is positioned proximate the faceplate 455 to facilitate processing operations. In the process position, the substrate support, and in particular support plate 413, may define at least a portion of a lower boundary of the processing region 405.

Each processing chamber 401 may include a seal plate 440 that is coupled with the shaft 411 and that extends below the support plate 413. For example, the seal plate 440 may have a greater diameter than the support plate 413 such that a peripheral edge of the seal plate 440 extends radially outward of a peripheral edge of the support plate 413. The seal plate 440 may include a top plate 441, which is substantially parallel with the support plate 413 and which defines the peripheral edge of the seal plate 440. The top plate 441 may define a central aperture that is sized to receive the shaft 411 of the substrate support 410. The top plate 441 may be directly coupled with the shaft 411 in some embodiments. In other embodiments, the seal plate 440 may include a collar 443, such as a cylindrical collar, that extends downward from an inner edge of the top plate 441 and couples with a base 445 that extends inward and couples the collar 443 and top plate 441 with the shaft 411. An upward-facing surface of the top plate 441 may include an RF gasket 447, which may be disposed radially outward of the peripheral edge of the support plate 413 and in alignment with a bottom surface of the pumping liner 460. Such positioning may enable the RF gasket 447 to seal the interface between the seal plate 440 and the bottom surface of the pumping liner 460 when the substrate support 410 (and seal plate 440) is in the process position. In some embodiments, RF gasket 447 may be an aluminum and/or stainless steel-cored O-ring, although other materials are possible. In some embodiments, in addition to the RF gasket 447, an additional chamber seal is included proximate the RF gasket 447 to help create an airtight seal at the interface between the seal plate 440 and the bottom surface of the pumping liner 460 when the substrate support 410 (and seal plate 440) is in the process position. For example, an elastomeric, encapsulated Teflon O-ring, and/or other seal may be provided proximate the RF gasket 447 to provide such sealing capabilities.

The sealed interface and the seal plate 440 may isolate the processing region 405 from the region below (e.g., a transfer region of the processing chamber 401, which may include cold components that may encourage formation of residue from process gases and byproducts) as well as from the transfer chamber 495 and any other processing chambers within the system 400. This isolation may reduce the amount of purge gas needed to be flowed below the substrate support 410 during processing operations (e.g., to prevent deposition gases from forming residue on chamber components below the processing region), which may increase the efficiency of process gases due to less dilution by such purge gases. The isolation also reduces the amount of chamber cleaning needed. Additionally, the RF gasket 447 may create a conductive return path for RF current to flow through the substrate support 410, seal plate 440, RF gasket 447, pumping liner 460, and lid plate 415 when in the process position.

In some embodiments, a small amount of purge gas may be flowed in a region between the seal plate 440 and the substrate support 410 to prevent any deposition gases from reaching such areas and forming deposits on the exposed surfaces. Additionally, purge gas may be flowed proximate the RF gasket 447 to prevent leakage of process gases through the interface of the RF gasket 447 and pumping liner 460 in the event that an airtight seal is not maintained (e.g., a small gap is present). Such purge gases may be introduced through one or more channels formed in the seal plate 440 and/or pumping liner 460.

In some embodiments, the components defining the processing region 405 (and the region itself) may be structurally symmetric. For example, the faceplate 455, dielectric spacer 475, pumping liner 460, substrate support 410, seal plate 440, and/or RF gasket 447 may each be symmetrical about a central axis of the respective component. Such designs may enable the processing region 405 to be symmetric with respect to each of gas flow, thermal distribution, and RF distribution, which may improve the deposition and film thickness uniformity of substrates processed therein.

Each chamber 401 may include a bellow 465 that extends along at least a portion of a length of the shaft 411 and that isolates an interior of the bellow 465 (and thus the shaft 411 and opening within the base 416 through which the shaft 411 extends) from a higher pressure environment (e.g., atmospheric conditions outside of the chamber environment). In a particular embodiment, the bellow 465 may extend between a bottom surface of the base 416 of the chamber body and a support 414 on which the shaft 411 of the substrate support 410 is mounted. The bellow 465 may be expandable and contractible along a length of the bellow 465 such that the interior of the bellow 465 remains isolated from the higher pressure environment as the substrate support 410 translates within the processing chamber 401. For example, as the substrate support 410 is raised the bellow 465 may be compressed between the bottom surface of the base 416 and the support 414 (as shown in FIG. 4B) and as the substrate support 410 is lowered the bellow 465 may expand (as shown in FIG. 4A). In other embodiments, the bellow 465 may extend between a top surface of the base 416 of the chamber body and a bottom surface of the seal plate 440. As the substrate support 410 is raised the bellow 465 may expand and as the substrate support 410 is lowered the bellow 465 may contract.

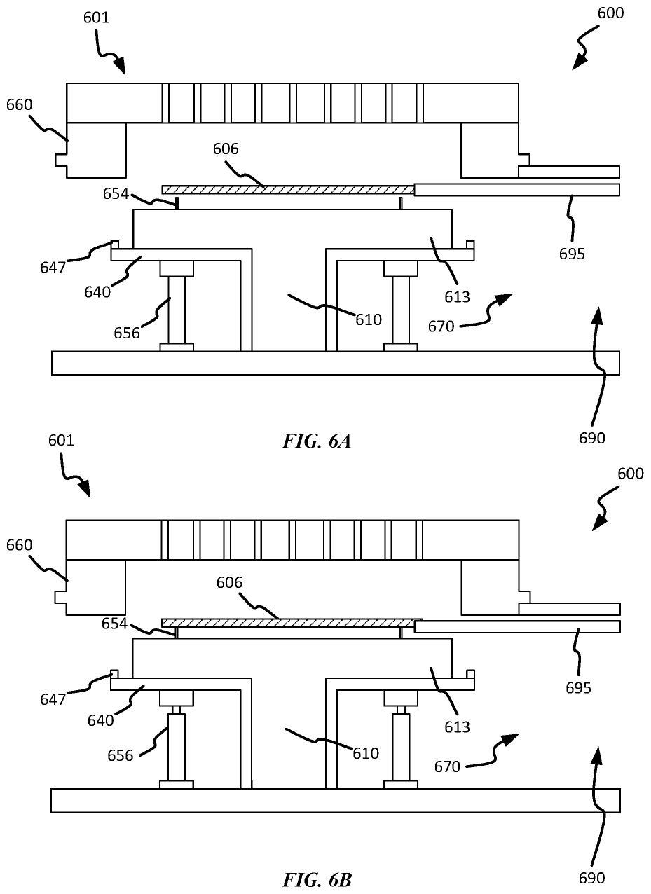

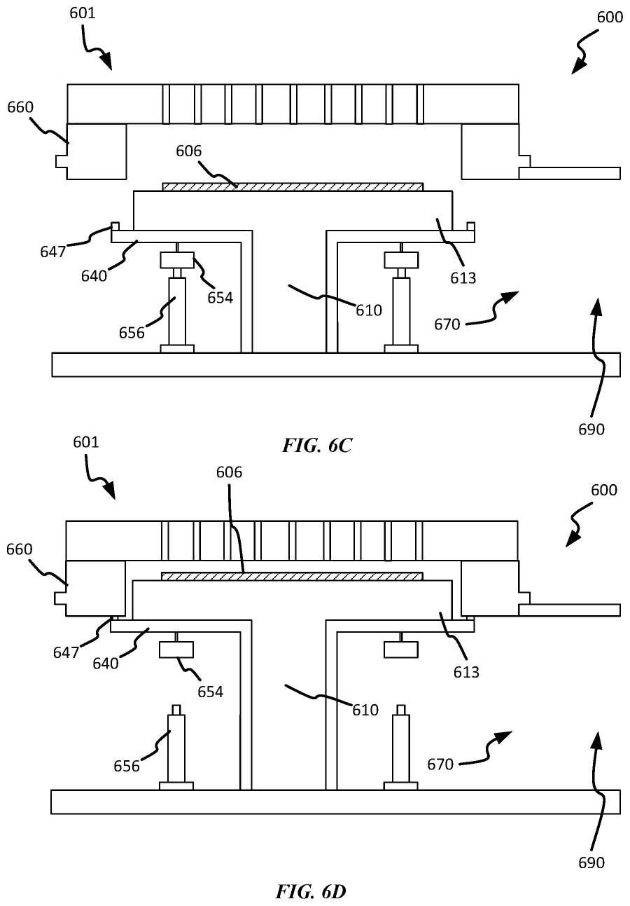

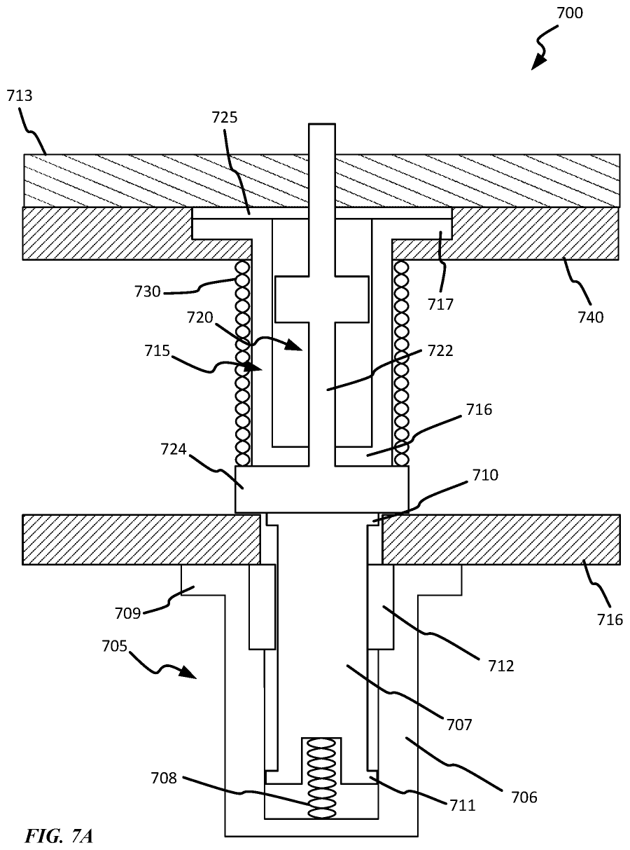

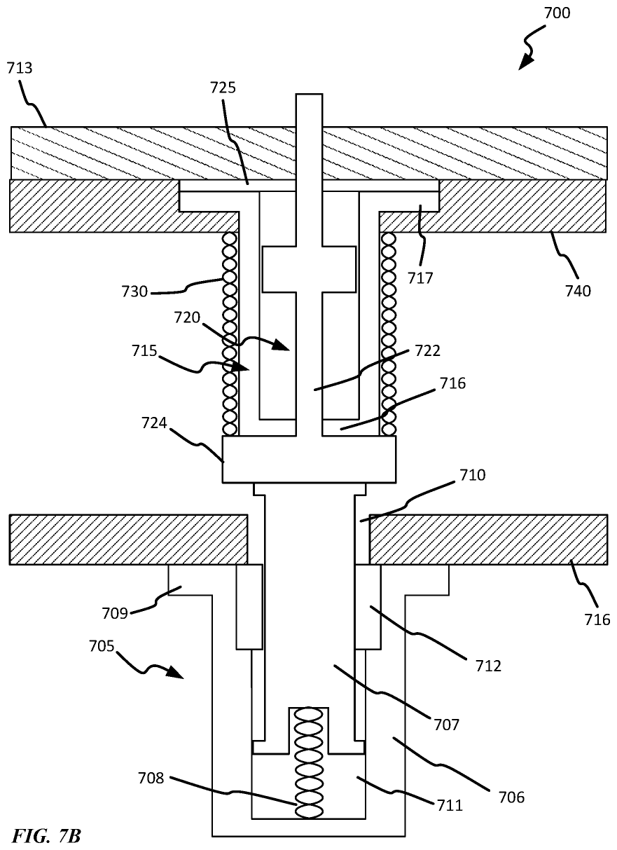

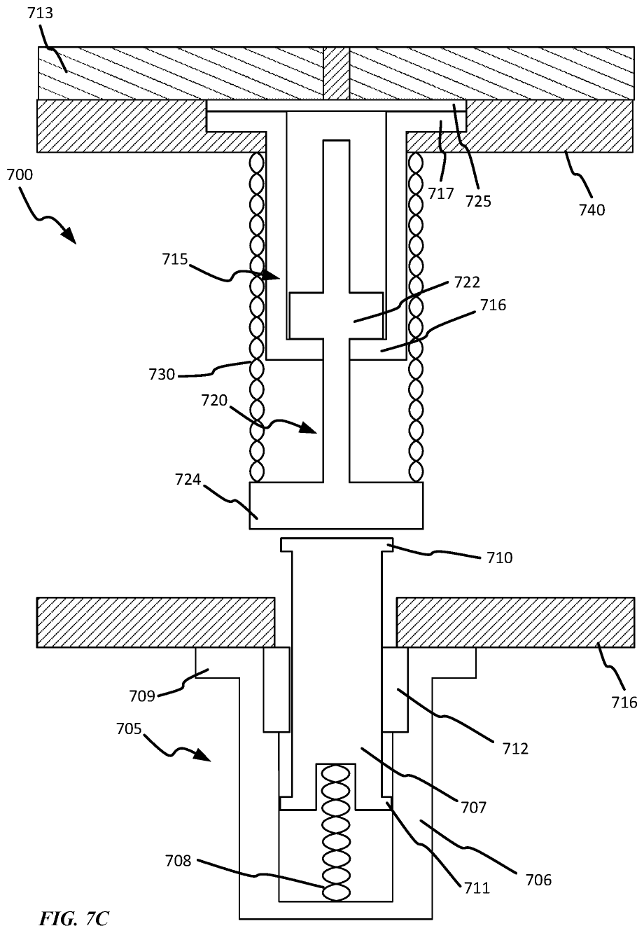

Each chamber 401 may include a number of lift pins 454 that are extendible through the support plate 413 to facilitate the transfer of substrates between the support plate 413 and the transfer apparatus 495. For example, the lift pins 454 may be movable between a recessed position that enables the substrate to sit directly against the surface of the support plate 413 and an extended position in which the substrate is lifted off of the surface of the support plate 413 and is engageable by the transfer apparatus 495. Each lift pin 454 may include an actuator 457 that may move the lift pin 454 between the recessed position and the extended position. In some embodiments, the actuator 457 may be an active actuator that includes a motor or other mechanism to move the lift pin 454. In other embodiments, such as described in relation to FIGS. 6A-7C, the actuator 457 may be passive and may be activated based on movement of the substrate support 410. For example, as the substrate support 410 is lowered, the lift pins 454 may transition to the extended state and when the substrate support 410 is raised, the lift pins 454 may transition to the recessed state. The actuators 457 may remain coupled with the lift pins 454 as the substrate support 410 is raised or may be disengaged from the lift pins 454 as the substrate support 410 is raised in various embodiments. For example, the actuators 457 may be spring-loaded plungers that are coupled with the base 416 and that bias the lift pins 454 upward until the substrate support 410 is raised to a particular height, at which point a head of the lift pins 454 may be lifted off of the spring-loaded plungers, which may remain attached to the base 416.

As noted above, FIG. 4A illustrates the substrate support 410 in the lowered transfer position. In the transfer position, the substrate support 410, seal plate 440, and RF gasket 447 are each vertically spaced apart from a bottom surface of the pumping liner 460 by a sufficient distance to provide clearance for the transfer apparatus 495 to load and unload substrates from the substrate support 410. Additionally, the lift pins 454 may be in the extended position to receive and/or handoff substrates with the transfer apparatus 495. In the transfer position, there is no completed RF circuit due to the separation between the RF gasket 447 and the pumping liner 460. As shown in FIG. 4B, in the process position the substrate support 410, seal plate 440, and RF gasket 447 are each elevated such that the RF gasket 447 is in contact with the bottom surface of the pumping liner 460 to complete an RF return path (e.g., from an RF power source, through the shaft 411, sealing plate 440, RF gasket 447, pumping liner 460, and lid plate 415). In the process position, the lift pins 454 may be in the recessed position such that the substrate 406 is fully supported by the surface of the support plate 413. The interface between the RF gasket 447 and the pumping liner 460 (along with the presence of the seal plate 440) may isolate the processing region 405 from an environment below the sealing plate 440 when the substrate support 410 and the seal plate 440 are in the process position. This may enable each processing region of the system 400 to be isolated from one another (and from the shared transfer chamber 490) during processing operations, and may prevent cross-contamination between chambers. Additionally, because the chambers 401 are isolated from one another during processing/cleaning operations, the chambers may be operated independently of one another, and may be used to perform the same or different processing/cleaning operations and/or operate at the same or different time.

As noted above, when in the process position, a closed radio frequency circuit is provided that allows radio frequency (RF) current to flow from a radio frequency source to one or more components of the system 400, such as to facilitate formation of plasma of a plasma-generator precursor within the processing region. For example, in some embodiments, the RF current may be supplied through the faceplate 455 and/or an upper RF electrode disposed within the lid stack and/or via the substrate support 410. In each instance, the presence of the RF gasket 447 on the seal plate 440 and contact of the RF gasket 447 with the pumping liner 460 in the process position may provide a continuous RF ground return. The symmetry of the ground path (e.g., via the RF gasket 447 and symmetrical chamber components) may improve plasma uniformity, while accommodating electrical decoupling of the seal plate 440 and RF gasket 447 from the pumping liner 460 during downward translation of the substrate support 410 within the system 400.

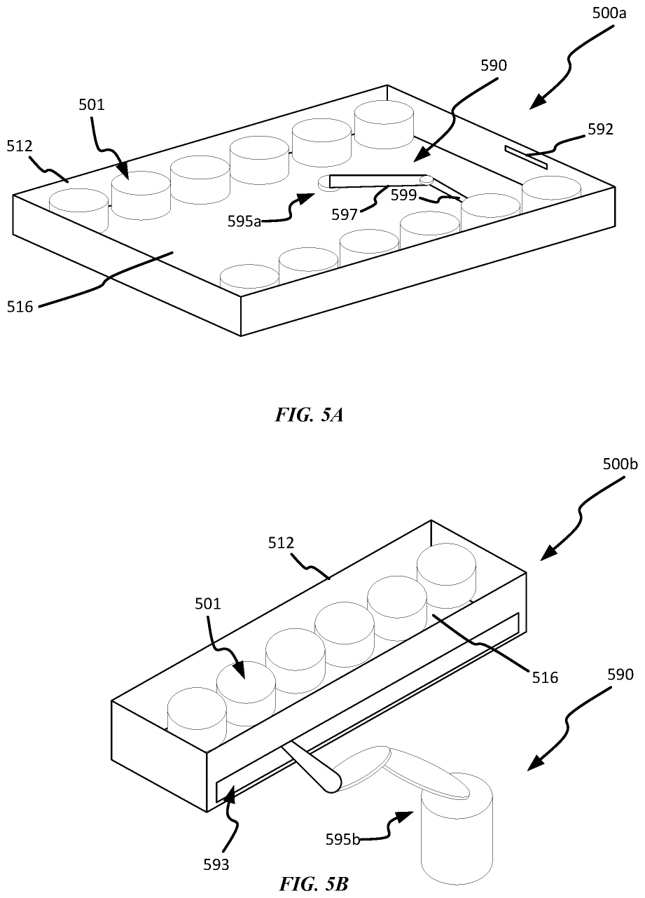

FIGS. 5A and 5B illustrate processing systems 500 that include a number of processing chambers 501 that are coupled with a single transfer chamber 590. Chambers 501 may be similar to any of the processing chambers described herein, such as chambers 108, 301, and/or 401. For example, each of the chambers 108, 301, and/or 401 may be arranged within a system 500 to share a single transfer chamber 590 as described below. The transfer chamber 590 may include one or more transfer apparatuses 595, with each transfer apparatus 595 including one or more robotic arms 597 and one or more end effectors 599 that may engage and transfer substrates between the various processing chambers 501 and one or more holding areas (not shown) or other chambers via one or more slit valves 592. In each system 500, the processing chambers 501 may each share at least one sidewall 512 and/or a base (or bottom surface) 516. In addition, the transfer chamber 590 may also share one or more sidewalls 512 and/or base 516 with one or more (or all) of the processing chambers 501. Such designs may simplify manufacturing and assembly of the components of system 500.

As illustrated, the processing chambers 501 may be arranged within a housing (e.g., the base 516 and sidewalls 512) in one or more rows. For example, in processing system 500a, the processing chambers 501 are arranged in two parallel rows on either side of a transfer apparatus 595. The system 500a includes a single slit valve 592 formed in one or more of the sidewalls 512 that enables the transfer apparatus 595a to transport substrates into and out of the housing. As illustrated, the slit valve 592 is sized to enable a single substrate to be transported into or out of the housing at a given time, although other configurations are possible, including configurations in which multiple slit valves and/or larger slit valves are incorporated into system 500a. In processing system 500b, the processing chambers 501 are arranged in a single row on one side of a transfer apparatus 595b, with sidewalls 512 separating the transfer chamber 590 and transfer apparatus 595b from the processing chambers 501. The system 500b includes an opening 593 formed in one or more of the sidewalls 512 that enables the transfer apparatus 595 to transport substrates into and out of the housing. As illustrated, the opening 593 is sized to enable a single transfer apparatus 595b to access each of the plurality of processing chambers 501, although other configurations are possible, including configurations in which multiple openings and/or different sizes of openings are incorporated into system 500b.

It will be appreciated that the above arrangements of processing chambers about one or more transfer apparatuses are merely provided as examples and that numerous variations exist. For example, the processing chambers may be provided on three, four, or more sides of a transfer apparatus, and the chambers may be arranged in rows and/or other arrays. Moreover, additional numbers and configurations of slit valves, openings, and/or other features may be utilized in various embodiments.

FIGS. 6A-6D show schematic side elevation views of a substrate transfer procedure using a processing system 600. Processing system 600 may include one or more chambers 601, which may be similar to any of the processing chambers described herein, such as chambers 108, 301, 401, and/or 501. Each chamber 601 may be coupled with a transfer chamber 690, which may include one or more transfer apparatuses 695, with each transfer apparatus 695 including one or more robotic arms and one or more end effectors that may engage and transfer substrates 606 between the processing chambers 601 and one or more holding areas (not shown) or other chambers. As illustrated in FIG. 6A, a substrate support 610 of the chamber 601 may be in a transfer position in which a support plate 613 is disposed below a level of an arm of the transfer apparatus 695. In the transfer position, lift pins 654 are in an extended position to enable an arm of the transfer robot to laterally move a substrate 606 through a slit valve or other opening 670 and to a position above the support plate 613. Once the substrate is positioned above the support plate 613, the substrate support 610 may be raised. As shown in FIG. 6B, as the substrate support 610 begins to raise, spring-loaded plungers 656 positioned below each lift pin 654 may begin to decompress and may bias the lift pins 654 in an upward direction to maintain the lift pins 654 in the extended position to engage a bottom surface of the substrate 606. Once the lift pins 654 are supporting the bottom surface of the substrate 606, the transfer apparatus 695 may release the substrate 606 and withdraw laterally from the chamber 601 via the slit valve or other opening 670. The substrate support 610 may then be raised further as shown in FIG. 6C. Once the spring-loaded plungers 656 reach a fully extended state (e.g., the springs are fully decompressed), the lift pins 654 begin to recess within the support plate 613 until the lift pins 654 are fully recessed and the substrate 606 is resting atop an upper surface of the support plate 613. The substrate support 610 may continue to be raised until the substrate support 610 reaches a final processing position as shown in FIG. 6D. In this position, the lift pins 654 may be hanging from a bottom of the support plate 613 (and/or seal plate 640), suspended above the spring-loaded plunger 656. Additionally, in the process position the substrate support 610, seal plate 640, and an RF gasket 647 may be each elevated such that the RF gasket 647 is in contact with a bottom surface of the pumping liner 660.

FIGS. 7A-7C show partial cross-sectional side elevation views of an exemplary lift pin or lift pin assembly 700 according to some embodiments of the present technology. The lift pin assembly 700 may be used as the lift pins in any of the chambers described herein, such as chambers 108, 301, 401, 501, and/or 601, as well as any other chamber or system. The lift pin assembly 700 may include any of the features described in relation to lift pins 261, 454, 654. As shown in FIG. 7A, the lift pin assembly 700 may include a spring-loaded plunger 705. The plunger 705 may include a base 706 that defines a central recess that is sized and shaped to slidingly receive a plunger body 707. The plunger body 707 may include an upper flange 710 and a lower flange 711. A bottom end of a compression spring 708 and/or other biasing element may be mounted within the central recess between the base 706 and the plunger body 707, with the spring 708 biasing the plunger body 707 in an upward direction away from a bottom of the central recess. An upper end of the spring 708 may be coupled with a lower end of the plunger body 707. The base 706 may include a mounting flange 709 that may be used to mount or otherwise couple the plunger with a portion of a processing chamber, such as with a base 716 of the chamber. An upper end of the central recess may have a narrower diameter than a lower end of the central recess. In some embodiments, to produce the narrower diameter, a sleeve insert 712 may be disposed within the central recess. The plunger body 707 may be inserted within the central recess such that the lower flange 711 is disposed below the sleeve insert 712 such that the narrower diameter of the sleeve insert 712 prevents the plunger body 707 from being pushed out of engagement with the central recess by the spring 708. Similarly, the upper flange 710 may prevent the plunger body 707 from being pushed too far into the central recess and may help prevent the spring 708 from being compressed too far.

Each lift pin assembly 700 may include a pin guide 715 that may be positioned above the plunger 705. The pin guide 715 may define a central aperture that may be sized to slidingly receive a pin body 722 of a pin member 720. A lower opening of the central aperture through a bottom surface of the pin guide 715 may have a smaller diameter than an upper region of the central aperture. The pin guide 715 may include a mounting flange 717 that may be used to secure the pin guide 715 to a portion of a substrate support (e.g., a support plate 713) and/or a sealing plate 740. The pin body 722 may have a variable diameter. For example, as illustrated a medial portion of the pin body 722 may have a greater diameter than the proximal end and distal end of the pin body 722, which may reduce the amount of material of the pin body 722 that may contact inner walls of the central recess of the pin guide 715 as well as permit the pin body 722 to slide along a length of the central aperture without falling out of the central aperture. For example, a cover plate 725 may be seated atop and coupled with the mounting flange 717, with the cover plate 725 defining a central aperture that is sized to slidingly receive the smaller diameter of the distal end of the pin body 722, thereby preventing the medial portion of the pin body 722 from being ejected or otherwise removed from an upper end of the central aperture of the pin guide 715. Similarly, the smaller diameter of the lower opening of the central aperture may be smaller than the medial portion of the pin body 722 and may prevent the medial portion of the pin body 722 from being ejected or otherwise removed from a lower end of the central aperture of the pin guide 715. The distal end of the pin body 722 may have a length that is sufficient to project above the upper surface of the support plate 713 of a substrate support when the lift pin assembly 700 is in a fully extended position (e.g., when the medial portion of the pin body 722 contacts a lower surface of the cover plate 725). While shown here with pin member 720 being a single component, it will be appreciated that other configurations are possible. For example, the pin member 720 may be in the form of a split pin, with a first member including a head 724, a proximal end, and the medial portion of the pin member 720, while a second member that includes the distal end of the pin member 720 is coupled with the medial portion of the pin member 720.

As noted above, the plunger 705 may be coupled with a base 716 of a processing chamber and may remain in a fixed position. The pin guide 715 may be coupled with a support plate 713 and/or seal plate 740 of a substrate support and may translate within the chamber along with the support plate 713 and/or seal plate 740. The operation of the lift pin assembly 700 may be similar to that described in relation to FIGS. 6A-6D. For example, the substrate support may be in a low, transfer position in which the support plate 713 and/or seal plate 740 are proximate the base of the chamber. As shown in FIG. 7A, in such a position, a head 724 of the pin member 720 is positioned atop the plunger body 707, with the plunger body 707 pushed downward within the central recess of the base 706 and compressing the spring 708. In such a position, the plunger body 707 pushes the head 724 upward such that the distal end of the pin body 722 protrudes above a top surface of the support plate 713 and the lift pin assembly 700 is in an extended position to transfer of a substrate to and from a transfer apparatus. Once the substrate is positioned above the support plate 713, the substrate support may be raised, which may enable the spring 708 to decompress and force the plunger body 707 upward to maintain the pin member 720 in the extended position to engage a bottom surface of the substrate as shown in

FIG. 7B. Once the transfer apparatus releases the substrate and withdraws from the chamber the substrate support may be raised further. Once the spring 708 reaches a fully extended state and the plunger body 707 is at a maximum height, the rising substrate support causes the pin member 720 to slide downward within the central aperture of the pin guide 715 until the pin member 720 is fully recessed within the substrate support and the substrate is resting atop an upper surface of the support plate 713. The pin member 720 may continue to move downward as the substrate support is raised until the medial portion of the pin body 720 contacts the bottom surface of the pin guide 715, at which point the downward travel of the pin member ceases and the pin member 720 is lifted from a top of the plunger body 707 and hangs from the support plate 713 and/or seal plate 740 as shown in FIG. 7C. In some embodiments, rather than hanging from the support plate 713 and/or seal plate 740, the plunger body/spring travel may be designed such that the spring 708 reaches a full amount of travel and the plunger body 707 is at a greatest height when the substrate support is in the full process position such that the head 724 of the pin member 720 does not disengage from the plunger body 707 at any point of travel of the pin member 720 and substrate support. In some such embodiments, the head 724 of the pin member 720 may be fixedly coupled with a top end of the plunger 707. For example, a top end of the plunger body 707 may define a recess that is sized to receive and grasp or otherwise engage an outer and/or top surface of the head 724 of the pin member 720.

In some embodiments, the lift pin assembly 700 may include a pin bellow 730. The pin bellow 730 may be positioned about the pin guide 715 and may help seal the lift pin assembly 700 to prevent any process gases from getting below the support plate 713 and/or seal plate 740 through lift pin apertures formed through the plate(s). The pin bellow 730 may be coupled with and between a lower surface of the support plate 713 and/or seal plate 713 and an upper surface of the head 724 of the pin body 720. The pin bellow 730 may expand and contract as the pin member 720 extends and recesses relative to the support plate 713. In embodiments in which the pin member 720 and plunger body 707 remain engaged throughout the translation of the substrate support, the pin bellow 730 may extend between the base 716 of the chamber and the lower surface of the support plate 713 and/or seal plate 740.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a region” includes a plurality of such regions, and reference to “the aperture” includes reference to one or more apertures and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing system, comprising:
a processing chamber comprising:
a chamber body comprising a sidewall and a base;
a pumping liner seated atop the chamber body;
a faceplate seated atop the pumping liner;
a substrate support disposed within the chamber body, the substrate support comprising a support plate and a shaft coupled with the support plate;
a seal plate that is coupled with the shaft and that extends below the support plate, the seal plate having a greater diameter than the support plate, wherein the seal plate comprises an RF gasket disposed radially outward of the support plate, wherein:
the substrate support and the seal plate are vertically translatable within the chamber body between a transfer position in which the RF gasket is vertically spaced apart from a bottom surface of the pumping liner and a process position in which the RF gasket is in contact with the bottom surface of the pumping liner; and
a processing region formed between the faceplate and the support plate is isolated from an environment below the sealing plate when the substrate support and the seal plate are in the process position.

2. The semiconductor processing system of claim 1, further comprising:
a dielectric spacer disposed between the pumping liner and the faceplate.

3. The semiconductor processing system of claim 1, wherein:
the pumping liner is symmetrical about a central axis.

4. The semiconductor processing system of claim 1, wherein:
the processing region is symmetrical with respect to each of gas flow, thermal distribution, and RF distribution.

5. The semiconductor processing system of claim 1, wherein:
the processing region is structurally symmetrical.

6. The semiconductor processing system of claim 1, further comprising:
a bellow that extends along at least a portion of a length of the shaft and that seals isolates an interior of the bellow from a higher pressure environment.

7. The semiconductor processing system of claim 6, wherein:
the bellow extends between a bottom surface of the base of the chamber body and a support on which the shaft of the substrate support is mounted.

8. The semiconductor processing system of claim 1, further comprising:
a plurality of lift pins that are extendible through the support plate, wherein each of the plurality of lift pins comprises:
a spring-loaded plunger that is coupled with the base of the chamber body; and
a pin member that is biased by the spring-loaded plunger in an upward direction.

9. The semiconductor processing system of claim 8, wherein:
each of the plurality of lift pins comprises a pin guide that is coupled with one or both of the seal plate and a head of the pin member.

10. The semiconductor processing system of claim 8, wherein:
each of the plurality of lift pins comprises a pin bellow that extends between the seal plate and the base of the chamber body.

11. The semiconductor processing system of claim 8, wherein:
the spring-loaded plunger and the pin member separate as the substrate support is raised to the process position such that the pin member hangs from the substrate support when in the process position.

12. The semiconductor processing system of claim 8, wherein:
the spring-loaded plunger comprises:
a base that is coupled with the base and that defines a central recess;
a plunger body that is slidingly received within the central recess; and
a spring that is coupled between a base of the central recess and a bottom end of the plunger body.

13. The semiconductor processing system of claim 1, further comprising:
a transfer chamber coupled with the processing chamber; and
at least one additional processing chamber that shares the base of the chamber body with the chamber and the transfer chamber, wherein the processing region of the processing chamber and a processing region of the at least one additional processing chamber are isolated from one another when the substrate support is in the process position.

14. A semiconductor processing system, comprising:
a transfer chamber that comprises at least one transfer apparatus;
a plurality of processing chambers that are horizontally aligned with one another, each of the plurality of processing chambers being coupled with the transfer chamber, wherein each of the plurality of processing chambers comprises:
a chamber body comprising a sidewall and a base, wherein an interior of the chamber body is accessible to the at least one transfer apparatus;
a pumping liner seated atop the chamber body;
a faceplate seated atop the pumping liner;
a substrate support disposed within the chamber body, the substrate support comprising a support plate and a shaft coupled with the support plate;
a seal plate that is coupled with the shaft and that extends below the support plate, the seal plate having a greater diameter than the support plate, wherein the seal plate comprises an RF gasket disposed radially outward of the support plate, wherein:
the substrate support and the seal plate are vertically translatable within the chamber body between a transfer position in which the RF gasket is vertically spaced apart from a bottom surface of the pumping liner and a process position in which the RF gasket is in contact with the bottom surface of the pumping liner; and
a processing region formed between the faceplate and the support plate is isolated from an environment below the sealing plate when the substrate support and the seal plate are in the process position.

15. The semiconductor processing system of claim 14, wherein:
the base of each of the plurality of processing chambers forms a bottom surface of the transfer chamber.

16. The semiconductor processing system of claim 14, wherein:
the plurality of processing chambers are arranged in a single row on one side of the at least one transfer apparatus.

17. The semiconductor processing system of claim 14, wherein:
the plurality of processing chambers are arranged in a plurality of rows on multiple sides of the at least one transfer apparatus.

18. The semiconductor processing system of claim 14, further comprising:
a lid plate that is seated atop the chamber body of each of the plurality of processing chambers.

19. A lift pin assembly, comprising:
a spring-loaded plunger;
a pin guide that is disposed above the spring-loaded plunger;
a pin member that is disposed within the pin guide and that is biased by the spring-loaded plunger in an upward direction; and
a pin bellow positioned about the pin guide and coupled with a head of the pin member.

20. The lift pin assembly of claim 19, wherein:
the pin member comprises split pins.
